(19) United States
(12) Patent Application Publication
(10) Pub. No.: US 2026/0016513 A1
(43) Pub. Date: Jan. 15, 2026

(54) CLOSED-LOOP CURRENT SENSOR AND OPERATION METHOD THEREOF

(71) Applicant: Delta Electronics, Inc., Taoyuan City (TW)

(72) Inventors: Tsung-Yu LIN, Taoyuan City (TW); Chia-Jung NIAN, Taoyuan City (TW); Kai-Wei HU, Taoyuan City (TW); Yuan-Kai LIN, Taoyuan City (TW)

(21) Appl. No.: 19/184,043

(22) Filed: Apr. 21, 2025

(30) Foreign Application Priority Data
Jul. 11, 2024 (CN) 202410929101.0

(51) Int. Cl. G01R 19/25; G01R 15/20; H02M 1/00

(52) U.S. Cl. CPC G01R 19/2513; G01R 15/202; H02M 1/0009

(57) ABSTRACT

A closed-loop current sensor is provided. The under-test current conversion unit inputs an under-test current, and generates an analog signal and a voltage output signal. The first signal conversion unit converts the analog signal into a magnetic flux signal. The second signal conversion unit converts the voltage output signal into a digital voltage output signal. In an open-loop state, the control unit outputs a control signal with a first duty cycle, and controls the current value of the under-test current conversion unit. The voltage output signal is a first reading value, and the analog signal is the residual magnetism value of the under-test current conversion unit. In the open-loop state, the driving circuit generates an alternating current on the coil as well as generates positive and negative currents and magnetic fields with a decreasing peak value on the under-test current conversion unit for degaussing.

### CROSS REFERENCE TO RELATED APPLICATIONS

This application patent application No. 202410929101.0, filed on Jul. 11, 2024, the entirety of which is incorporated by reference herein.

### BACKGROUND OF THE INVENTION

### Field of the Invention

The present invention relates to a sensor, and in particular it relates to a closed-loop current sensor and an operation method thereof.

### Description of the Related Art

Generally speaking, current sensors are used to sense the under-test current generated by an electronic device. Since the magnetic field measurement range of the iron core in an open-loop current sensor is large, the proportion of offset caused by the residual magnetism of the iron core is low. However, in a closed-loop current sensor, the operating point of the magnetic field is kept at zero. When there is residual magnetism in the iron core, the offset of the driving voltage, component error, etc. exist, if degaussing is not performed in the initial state, the output of the closed-loop sensor may be seriously offset. Therefore, how to effectively perform internal degaussing of the current sensor has become an important issue.

### BRIEF SUMMARY OF THE INVENTION

An embodiment of the present invention provides a closed-loop current sensor and an operation method thereof, so that the closed-loop current sensor may perform the internal degaussing when the power is turned on every time, without the need for additional coils or hardware circuits to perform the degaussing operation. This may avoid the residual magnetism caused by the imbalance of the drop of the positive and negative voltages at the coil terminal during a power outage, or the residual magnetism generated by the induction of external magnetic fields during shutdown.

An embodiment of the present invention provides a closed-loop current sensor, which includes an under-test current conversion unit, a first signal conversion unit, a second signal conversion unit, a control unit and a driving circuit. The under-test current conversion unit is configured to input an under-test current, and generate an analog signal and a voltage output signal. The first signal conversion unit is configured to receive the analog signal, and convert the analog signal into a magnetic flux signal. The second signal conversion unit is configured to receive the voltage output signal, and convert the voltage output signal into a digital voltage output signal. The control unit is electrically connected to the first signal conversion unit and the second signal conversion unit, and configured to receive the magnetic flux signal and the digital voltage output signal. In an open-loop state, the control unit is configured to output a second control signal with a first duty cycle and to control the current value of a coil of the under-test current conversion unit, the voltage output signal is a first reading value, and the analog signal is also controlled to be a residual magnetism value of an iron core of the under-test current conversion unit. The driving circuit is electrically connected to the control unit and under-test current conversion unit. In the open-loop state, the driving circuit is configured to generate an alternating current signal, so as to generate positive and negative currents with a decreasing peak value on the coil and generate positive and negative magnetic fields with a decreasing peak value on the iron core for degaussing.

An embodiment of the present invention provides an operation method of a closed-loop current sensor, which includes the following steps. The under-test current conversion unit is provided to input an under-test current, and generate an analog signal and a voltage output signal. A first signal conversion unit is provided to receive the analog signal, and convert the analog signal into a magnetic flux signal. A second signal conversion unit is provided to receive the voltage output signal, and convert the voltage output signal into a digital voltage output signal. The control unit is provided to be electrically connected to the first signal conversion unit and the second signal conversion unit, and to receive the magnetic flux signal and the digital voltage output signal. The driving circuit is provided to be electrically connected to the control unit and under-test current conversion unit. In an open-loop state, the control unit is used to output a control signal with a first duty cycle and to control the current value of a coil of the under-test current conversion unit, wherein the voltage output signal is a first reading value, and the analog signal is also controlled to be a residual magnetism value of an iron core of the under-test current conversion unit. In the open-loop state, the driving circuit is used to generate an alternating current signal, so as to generate positive and negative currents with a decreasing peak value on the coil and generate positive and negative magnetic fields with a decreasing peak value on the iron core for degaussing.

According to the closed-loop current sensor and the operation method thereof disclosed by the present invention, in the closed-loop state, in the open-loop state, the control unit outputs the control signal with the first duty cycle and controls the current value of the coil of the under-test current conversion unit, the voltage output signal is the first reading value, and the analog signal is also controlled to be the residual magnetism value of the iron core of the under-test current conversion unit. In the open-loop state, the driving circuit generates the alternating current signal, so as to generate the positive and negative currents with a decreasing peak value on the coil and generate the positive and negative magnetic fields with a decreasing peak value on the iron core for degaussing. Therefore, the closed-loop current sensor may perform the internal degaussing when the power is turned on every time, without the need for additional coils or hardware circuits to perform the degaussing operation. This may avoid the residual magnetism caused by the imbalance of the drop of the positive and negative voltages at the coil terminal during a power outage, or the residual magnetism generated by the induction of external magnetic fields during shutdown.

### BRIEF DESCRIPTION OF THE DRAWINGS

The present invention can be more fully understood by reading the subsequent detailed description and examples with references made to the accompanying drawings, wherein:

FIG. 1 is a block diagram of a closed-loop current sensor according an embodiment of the present invention;

FIG. 2 is a schematic structural view of a closed-loop current sensor according an embodiment of the present invention;

FIG. 3 is a waveform diagram of a sinusoidal signal with a decreasing peak value having a third duty cycle according an embodiment of the present invention;

FIG. 4A to FIG. 4D are schematic views of a hysteresis curve of a closed-loop current sensor according an embodiment of the present invention;

FIG. 5 is a flowchart of an operation method of a closed-loop current sensor according an embodiment of the present invention; and

FIG. 6A and FIG. 6B are a flowchart of an operation method of a closed-loop current sensor according another embodiment of the present invention.

### DETAILED DESCRIPTION OF THE INVENTION

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, a person skilled in the art would selectively implement all or some technical features of any embodiment of the disclosure or selectively combine all or some technical features of the embodiments of the disclosure.

In each of the following embodiments, the same reference number represents an element or component that is the same or similar.

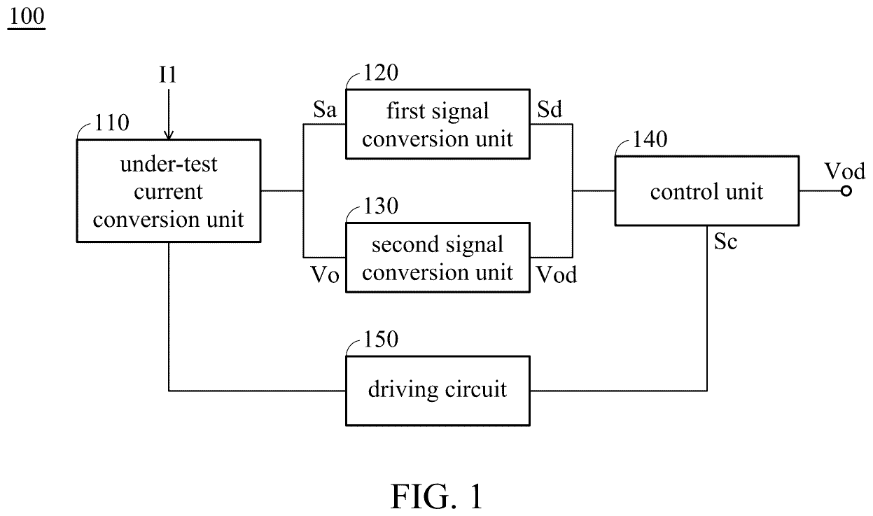

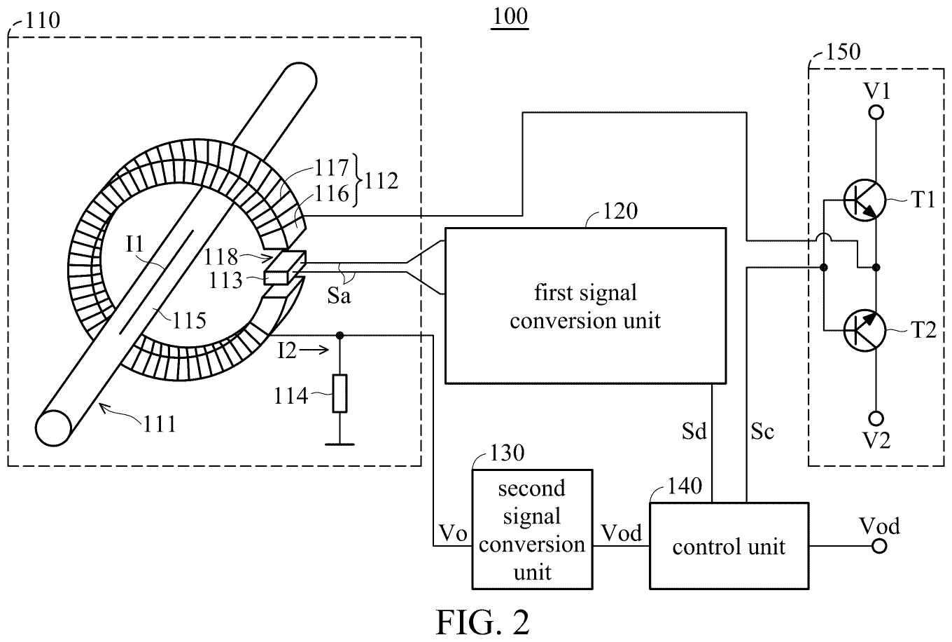

FIG. 1 is a block diagram of a closed-loop current sensor according an embodiment of the present invention. FIG. 2 is a schematic structural view of a closed-loop current sensor according an embodiment of the present invention. Please refer to FIG. 1 and FIG. 2. The closed-loop current sensor 100 includes an under-test current conversion unit 110, a first signal conversion unit 120, a second signal conversion unit 130, a control unit 140 and a driving circuit 150.

The under-test current conversion unit 110 may input an under-test current I1, and generate an analog signal Sa and a voltage output signal Vo. Furthermore, the under-test current conversion unit 110 may generate the analog signal Sa through an induced magnetic field generated by the under-test current I1. In the embodiment, the above analog signal Sa may be a magnetic flux signal and is a differential signal.

The first signal conversion unit 120 may be electrically connected to the under-test current conversion unit 110. The first signal conversion unit 120 may receive the analog signal Sa, and convert the analog signal Sa into a magnetic flux signal Sd. In the embodiment, the above magnetic flux signal Sd may be a digital signal. In some embodiments, the first signal conversion unit 120 may be an analog-to-digital converter (ADC) or a delta-sigma modulator, but the present invention is not limited thereto.

The second signal conversion unit 130 may be electrically connected to the under-test current conversion unit 110. The second signal conversion unit 130 may receive the voltage output signal Vo, and convert the voltage output signal Vo into a digital voltage output signal Vod. In some embodiments, the second signal conversion unit 130 may be an analog-to-digital converter or a delta-sigma modulator, but the present invention is not limited thereto.

The control unit 140 may be electrically connected to the first signal conversion unit 120 and the second signal conversion unit 130. The control unit 140 may receive the magnetic flux signal Sd of the first signal conversion unit 120 and the digital voltage output signal Vod of the second signal conversion unit 130. In some embodiments, the control unit 140 may be a digital signal processor, an application-specific integrated circuit, a micro control unit, or a field programmable logic gate array, but the present invention is not limited thereto.

In addition, in an open-loop state, the control unit 140 may output a control signal Sc with a first duty cycle and to control the current value of a coil (such as the coil 117 of FIG. 2) of the under-test current conversion unit 110, the voltage output signal Vo is a first reading value, and the analog signal Sa is also controlled to be a residual magnetism value of an iron core (such as the iron core 116 of FIG. 2) of the under-test current conversion unit 110. Furthermore, in some embodiments, the duty cycle is defined as between plus and minus 100%, and the control unit 140 may further output the control signal with a second duty cycle, wherein the second duty cycle is different than the first duty cycle. In some embodiments, the second duty cycle is, for example, 0%, and the first duty cycle is, for example, one of the values between −10% and 10%, but the present invention is not limited thereto. In addition, the one of the values between −10% and 10% is, for example, 5%, but the present invention is not limited thereto.

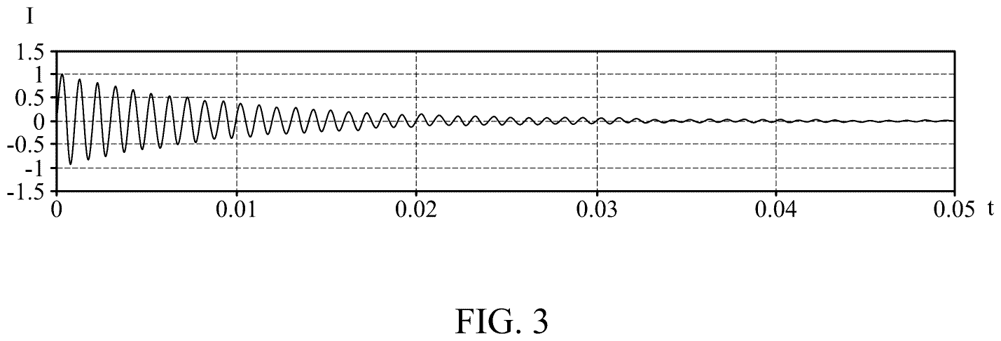

Moreover, the control unit 140 may further output the control signal Sc with the first duty cycle plus a sinusoidal signal with a decreasing peak value having a third duty cycle, wherein the third duty cycle is different than the first duty cycle. In the embodiment, the third duty cycle is, for example, 80%, and the sinusoidal signal with the decreasing peak value of the third duty cycle is as shown in FIG. 3, but the embodiment of the present invention is not limited thereto. In addition, the sinusoidal signal with the decreasing peak value of the third duty cycle may be expressed as Ddemag*sin(wt)*e−t, wherein Ddemag is the third duty cycle.

The driving circuit 150 may be electrically connected to the control unit 140 and under-test current conversion unit 110. In the open-loop state, the driving circuit 150 may generate an alternating current signal, so as to generate positive and negative currents with a decreasing peak value on the coil (such as the coil 117 of FIG. 2) and generate positive and negative magnetic fields with a decreasing peak value on the iron core (such as the iron core 116 of FIG. 2) for degaussing. Furthermore, the driving circuit 140 may further generate the alternating current signal according to the control signal Sc with the first duty cycle plus the sinusoidal signal with the decreasing peak value having the third duty cycle, so as to generate the positive and negative currents with a decreasing peak value on the coil (such as the coil 117 of FIG. 2) and generate the positive and negative magnetic fields with a decreasing peak value on the iron core (such as the iron core 116 of FIG. 2) for degaussing. Therefore, the closed-loop current sensor 100 may perform the internal degaussing when the power is turned on every time, without the need for additional coils or hardware circuits to perform the degaussing operation. This may avoid the residual magnetism caused by the imbalance of the drop of the positive and negative voltages at the coil 117 terminal during a power outage, or the residual magnetism generated by the induction of external magnetic fields during shutdown.

In some embodiments, in a closed-loop state, the control unit 140 may output the control signal Sc with the first duty cycle plus a corresponding reverse magnetic field, so as to control the current value of the coil (such as the coil 117 of FIG. 2) of the under-test current conversion unit 110. That is, the driving circuit 150 may receive the control signal Sc with the first duty cycle plus the corresponding reverse magnetic field, and generate the reverse magnetic field in the under-test current conversion unit 110 to offset the induced magnetic field of the under-test current I1. In addition, the above control signal Sc may be a pulse width modulation (PWM) signal. Therefore, the closed-loop current sensor 100 may have no residual magnetism and fast response, and it may reduce the influence of the closed-loop current sensor 100 on electromagnetic interference and the driving power consumption, and reduce the use of subsequent state operation amplifier (OPA) circuits and reduce the sampling noise and delay of the signal.

In some embodiments, the control unit 140 may convert the magnetic flux signal Sd into the control signal Sc, and output the digital voltage output signal Vod. In addition, the digital voltage output signal Vod may be output to a subsequent state circuit, so that the subsequent stage circuit may obtain the magnitude of the under-test current and perform the corresponding applications, wherein the subsequent stage circuit may be another suitable processor or controller, but the present invention is not limited thereto.

In some embodiments, the under-test current conversion unit 110 may include a primary side 111, a secondary side 112, a magnetic unit 113 and a voltage generating unit 114, as shown in FIG. 2. The primary side 111 may input the under-test current I1, and generate a magnetic field. In some embodiments, the primary side 111 may include a current conductor 115, and the under-test current I1 is input into the current conductor 115 to generate the magnetic field.

The secondary side 112 may induce the magnetic field generated by the primary side 111 and generate an induced magnetic field, and may generate a current I2 through a driving of the driving circuit 150 and generate a reverse magnetic field, so as to offset the induced magnetic field of the above under-test current I1. In some embodiments, the secondary side 112 may include an iron core 116 and a coil 117. The current conductor 115 may be provided through the iron core 116. The iron core 116 may induce the magnetic field generated by the primary side 111 and generate the induced magnetic field. In addition, the iron core 116 may have a gap 118. The coil 117 may be disposed on the iron core 116. The coil 117 may generate the current I2 through the driving of the driving circuit 150 and generate the reverse magnetic field.

The magnetic unit 113 may be disposed in the gap 118 of the iron core 116. The magnetic unit 113 may generate the analog signal Sa by sensing the induced magnetic field of the gap 118 of the iron core 116. In the embodiment, the magnetic unit 113 may be a Hall sensor or another suitable sensor, but the present invention is not limited thereto.

The voltage generating unit 114 may be electrically connected to the secondary side 112. Furthermore, the voltage generating unit 114 may include a first terminal and a second terminal. The first terminal of the voltage generating unit 114 may be electrically connected to the coil 117 of the secondary side 112. The second terminal of the voltage generating unit 114 may be electrically connected to a ground terminal. The voltage generating unit 114 may receive the current I2 generated by the coil 117 and generate voltage output signal Vo. In the embodiment, the voltage generating unit 114 may be a resistor, but the present invention is not limited thereto.

In the embodiments, the driving circuit 150 may include a first transistor T1 and a second transistor T2. The first transistor T1 has a first terminal, a second terminal and a control terminal. The first terminal of the first transistor T1 may receive a first reference voltage V1. The second terminal of the first transistor T1 may be electrically connected to the under-test current conversion unit 110. Furthermore, the second terminal of the first transistor T1 may be electrically connected to the coil 117 of the secondary side 112 of the under-test current conversion unit 110, so as to drive the coil 117 to generate the current I2. The control terminal of the first transistor T1 may be electrically connected to the control unit 140 and receive the control signal Sc.

The second transistor T2 has a first terminal, a second terminal and a control terminal. The first terminal of the second transistor T2 may receive a second reference voltage V2. The second terminal of the second transistor T2 may be electrically connected to the second terminal of the first transistor T1. The control terminal of the second transistor T2 is electrically connected to the control terminal of the first transistor T1.

In the embodiment, the first transistor T1 and the second transistor T2 may be form a totem pole circuit. In addition, each of the first transistor T1 and the second transistor T2 may be a bipolar junction transistor (BJT), wherein the first terminal of each of the first transistor T1 and the second transistor T2 is, for example, a collector terminal, the second terminal of each of the first transistor T1 and the second transistor T2 is, for example, an emitter terminal, and the control terminal of each of the first transistor T1 and the second transistor T2 is, for example, a base terminal, but the present invention is not limited thereto.

In other embodiments, each of the first transistor T1 and the second transistor T2 may be a metal oxide semiconductor field effect transistor (MOSFET), wherein the first terminal of each of the first transistor T1 and the second transistor T2 is, for example, a drain terminal, the second terminal of each of the first transistor T1 and the second transistor T2 is, for example, a source terminal, and the control terminal of each of the first transistor T1 and the second transistor T2 is, for example, a gate terminal.

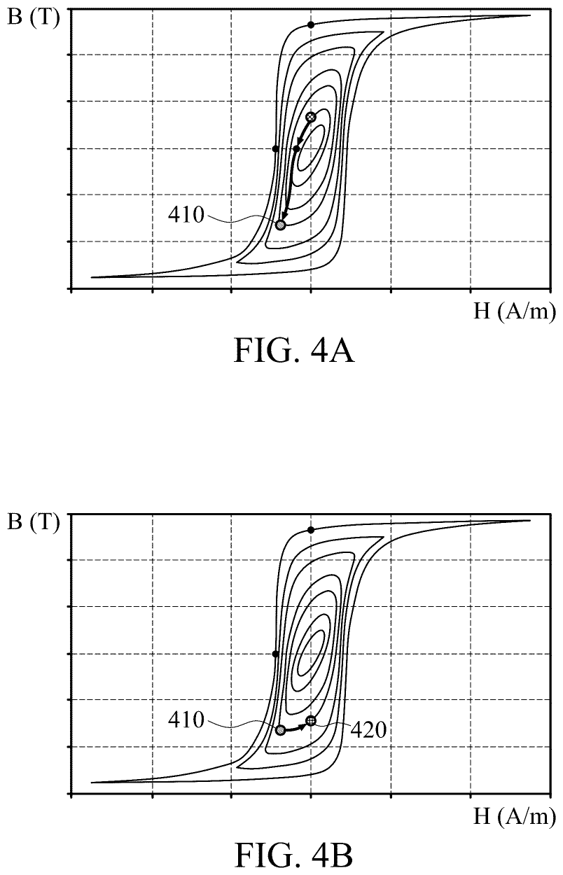

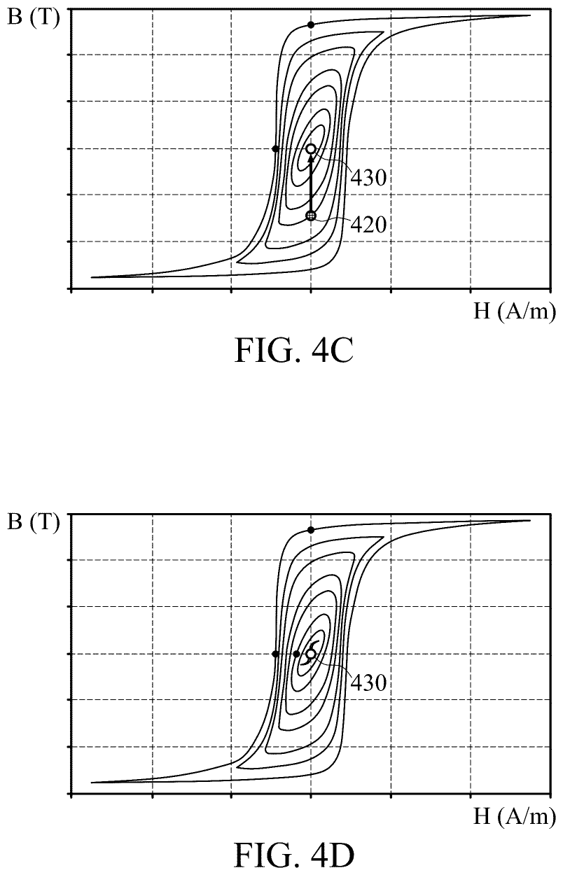

In an entire operation of the closed-loop current sensor 100, in the open-loop state, first, the control unit 140 may output the control signal Sc with the second duty cycle (such as 0%) to the driving circuit 150, so that the driving circuit 150 generates the driving signal to the under-test current conversion unit 110, so as to control the under-test current conversion unit 110. Due the inconsistent impedance or conduction voltage drop of the upper arm (such as the first transistor T1) and the lower arm (such as the second transistor T2) of the driving circuit 150, the accuracy error of the second duty cycle, or the positive and negative voltage errors, the driving circuit 150 generates the driving signal with non-zero deviation current, so that the iron core 116 of the under-test current conversion unit 110 includes the residual magnetism and a magnetic field (corresponding to the position 410 as shown in FIG. 4A). That is, through the above operation, the position of the hysteresis curve corresponding to the iron core 116 is position 410.

Then, the control unit 140 may output the control signal Sc with the first duty cycle (such as the one of the values between −10% and 10% (such as 5%)) to the diving circuit 150, so as to finely adjust the driving signal generated by the driving circuit 150. At this time, the driving circuit 150 may generate the corresponding driving signal to the under-test current conversion unit 110 according to the control signal Sc with the first duty cycle (such as 5%) and control the current value of the coil 117 of the under-test current conversion unit 110 (such as the current value of the current I2), so that the first reading value corresponding to the voltage output signal Vo output by the under-test current conversion unit 110 is zero (i.e., the voltage output signal Vo received by the second signal conversion unit 130 is zero), and the analog signal Sa output by the under-test current conversion unit 110 is also controlled to be the residual magnetism value of the iron core 116 of the under-test current conversion unit 110.

That is, through the control of the control signal Sc with the first duty cycle (such as the one of the values between −10% and 10% (such as 5%)) output by the control unit 140, the magnetic field on the iron core 116 may be eliminated (for example, the magnetic field at the position 410 in FIG. 4A or FIG. 4B is eliminated), so that the iron core 116 only include the residual magnetism (corresponding to the position 420 as shown in FIG. 4B). That is, through the above operation, the position of the iron core 116 corresponding the hysteresis curve is changed from the position 410 to the position 420.

Afterward, the control unit 140 may output the control signal Sc with the first duty cycle (such a 5%) plus the sinusoidal signal (as shown in FIG. 3) with the decreasing peak value of the third duty cycle (such as 80%) to the driving circuit 150, so that the driving circuit 150 generates the corresponding alternating current signal to the under-test current conversion unit 110 the control signal Sc with the first duty cycle (such a 5%) plus the sinusoidal signal with the decreasing peak value of the third duty cycle (such as 80%), so as to generate the positive and negative currents with a decreasing peak value on the coil 117 of the under-test current conversion unit 110 and generate the positive and negative magnetic fields with a decreasing peak value on the iron core 116 for degaussing, thereby eliminating the residual magnetism on the iron core 116 to close to zero (such as the position 430 as shown in FIG. 4C or FIG. 4D). That is, through the above operation, the position of hysteresis curve corresponding to the iron core 116 is changed from the positon 420 to the position 430. Therefore, the closed-loop current sensor 100 may perform the internal degaussing when the power is turned on every time, without the need for additional coils or hardware circuits to perform the degaussing operation. This may avoid the residual magnetism caused by the imbalance of the drop of the positive and negative voltages at the coil 117 terminal during a power outage, or the residual magnetism generated by the induction of external magnetic fields during shutdown. In addition, In FIG. 4A to FIG. 4D, B(T) represents the magnetic induction intensity, and H(A/m) represent the magnetic field intensity.

Afterward, in the closed-loop state, the control unit 140 may output the control signal Sc with the first duty cycle (such as 5%) plus the corresponding reverse magnetic field to the driving circuit 150, so as to control the current value of the coil of the under-test current conversion unit 110. That is, the control unit 140 may output the control signal Sc with the first duty cycle (such as 5%) plus the corresponding reverse magnetic field to the driving circuit 150, so that the driving circuit 150 receive the control signal Sc of the control unit 140 and generates the reverse magnetic field in the under-test current conversion unit 110 to offset the induced magnetic field of the under-test current I1. At this time, the under-test current conversion unit 110 receives the under-test current I1 and generates the voltage output signal Vo. Therefore, the closed-loop current sensor 100 may have no residual magnetism and fast response, and it may reduce the influence of the closed-loop current sensor 100 on electromagnetic interference and the driving power consumption, and reduce the use of subsequent state operation amplifier circuits and reduce the sampling noise and delay of the signal.

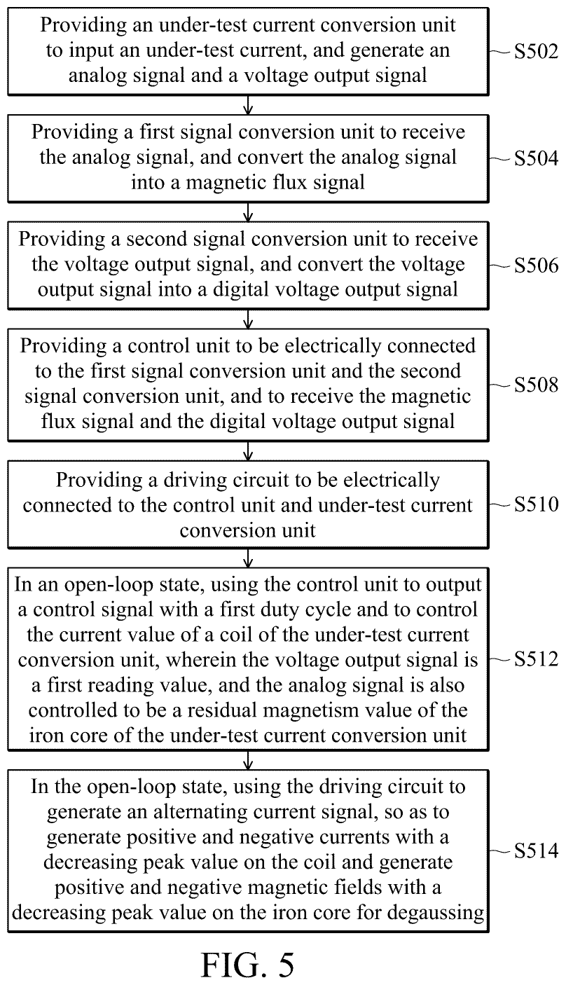

FIG. 5 is a flowchart of an operation method of a closed-loop current sensor according an embodiment of the present invention. In step S502, the method involves providing an under-test current conversion unit to input an under-test current, and generate an analog signal and a voltage output signal. In step S504, the method involves providing a first signal conversion unit to receive the analog signal, and convert the analog signal into a magnetic flux signal. In step S506, the method involves providing a second signal conversion unit to receive the voltage output signal, and convert the voltage output signal into a digital voltage output signal.

In step S508, the method involves providing a control unit to be electrically connected to the first signal conversion unit and the second signal conversion unit, and to receive the magnetic flux signal and the digital voltage output signal. In step S510, the method involves providing a driving circuit to be electrically connected to the control unit and under-test current conversion unit. In step S512, the method involves in an open-loop state, using the control unit to output a control signal with a first duty cycle and to control the current value of a coil of the under-test current conversion unit, wherein the voltage output signal is a first reading value, and the analog signal is also controlled to be a residual magnetism value of the iron core of the under-test current conversion unit. In step S514, the method involves in the open-loop state, using the driving circuit to generate an alternating current signal, so as to generate positive and negative currents with a decreasing peak value on the coil and generate positive and negative magnetic fields with a decreasing peak value on the iron core for degaussing.

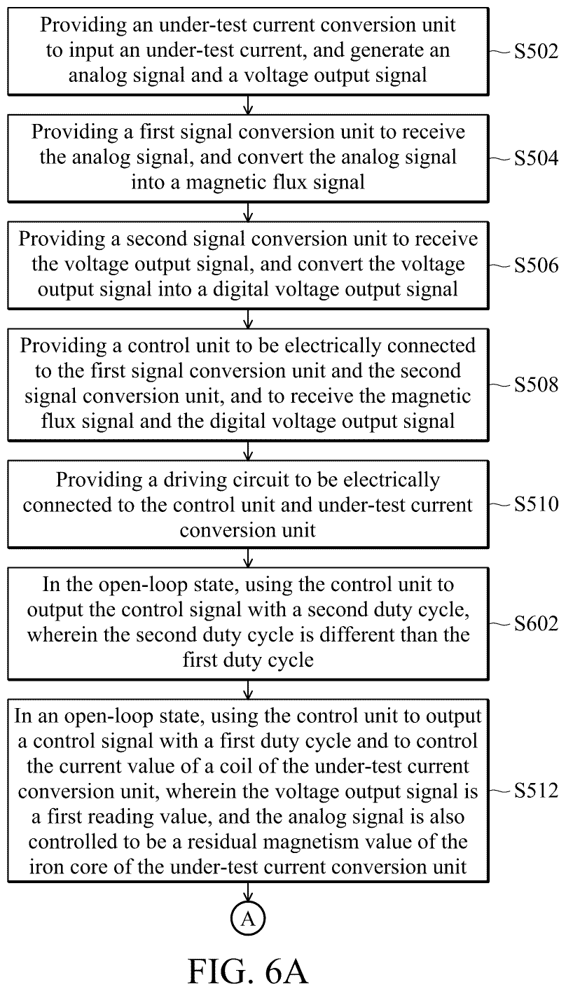

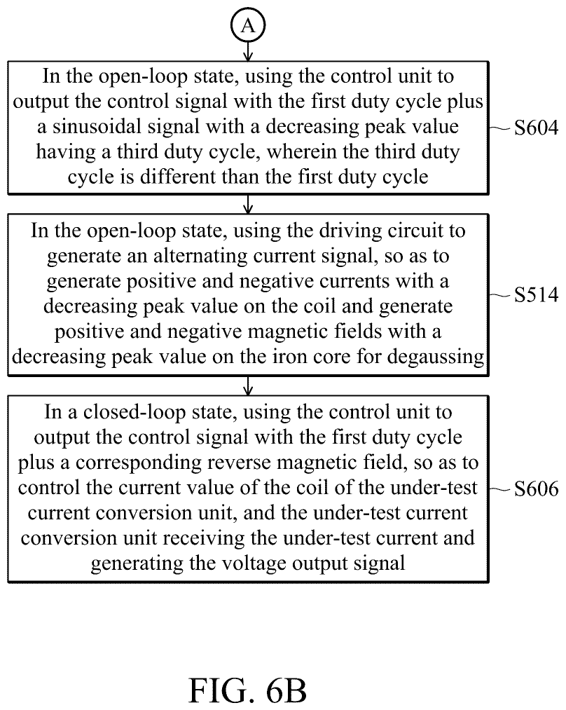

FIG. 6A and FIG. 6B are a flowchart of an operation method of a closed-loop current sensor according another embodiment of the present invention. In the embodiment, steps S502˜S514 in FIG. 6A and FIG. 6B are the same as or similar to steps S502˜S514 in FIG. 5. Accordingly, steps S502˜514 in FIG. 6A and FIG. 6B may refer to the description of the embodiment of FIG. 5, and the description thereof is not repeated herein.

In step S602, the method involves in the open-loop state, using the control unit to output the control signal with a second duty cycle, wherein the second duty cycle is different than the first duty cycle. In step S604, the method involves in the open-loop state, using the control unit to output the control signal with the first duty cycle plus a sinusoidal signal with a decreasing peak value having a third duty cycle, wherein the third duty cycle is different than the first duty cycle. Furthermore, step S514 includes using the driving unit to generate the alternating current signal according to the control signal with the first duty cycle plus the sinusoidal signal with the decreasing peak value of the third duty cycle. In step S606, the method involves in a closed-loop state, using the control unit to output the control signal with the first duty cycle plus a corresponding reverse magnetic field, so as to control the current value of the coil of the under-test current conversion unit, and the under-test current conversion unit receiving the under-test current and generating the voltage output signal.

It should be noted that the order of steps in FIG. 5, FIG. 6A and FIG. 6B is only for illustrative purposes, and is not intended to limit the order of steps of the present disclosure. The user may change the order of the steps above according the requirement thereof. The flowcharts described above may add additional steps or use fewer steps without departing from the spirit and scope of the present disclosure.

In summary, according to the closed-loop current sensor and the operation method thereof disclosed by the embodiment of the present invention, in the open-loop state, the control unit outputs the control signal with the first duty cycle and controls the current value of the coil of the under-test current conversion unit, the voltage output signal is the first reading value, and the analog signal is also controlled to be the residual magnetism value of the iron core of the under-test current conversion unit. In the open-loop state, the driving circuit generates the alternating current signal, so as to generate the positive and negative currents with a decreasing peak value on the coil and generate the positive and negative magnetic fields with a decreasing peak value on the iron core for degaussing. Therefore, the closed-loop current sensor may perform the internal degaussing when the power is turned on every time, without the need for additional coils or hardware circuits to perform the degaussing operation. This may avoid the residual magnetism caused by the imbalance of the drop of the positive and negative voltages at the coil terminal during a power outage, or the residual magnetism generated by the induction of external magnetic fields during shutdown.

In addition, in the embodiment of the present application, in the closed-loop state, the control unit outputs the control signal with the first duty cycle plus the corresponding reverse magnetic field, so as to control the current value of the coil of the under-test current conversion unit, the under-test current conversion unit receives the under-test current and generates the voltage output signal. Therefore, the closed-loop current sensor may have no residual magnetism and fast response, and it may reduce the influence of the closed-loop current sensor on electromagnetic interference and the driving power consumption, and reduce the use of subsequent state operation amplifier circuits and reduce the sampling noise and delay of the signal.

While the present invention has been described by way of example and in terms of the preferred embodiments, it should be understood that the present invention is not limited to the disclosed embodiments. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A closed-loop current sensor, comprising:
an under-test current conversion unit, configured to input an under-test current, and generate an analog signal and a voltage output signal;
a first signal conversion unit, configured to receive the analog signal, and convert the analog signal into a magnetic flux signal;
a second signal conversion unit, configured to receive the voltage output signal, and convert the voltage output signal into a digital voltage output signal;
a control unit, electrically connected to the first signal conversion unit and the second signal conversion unit, and configured to receive the magnetic flux signal and the digital voltage output signal, wherein in an open-loop state, the control unit is configured to output a control signal with a first duty cycle and to control a current value of a coil of the under-test current conversion unit, the voltage output signal is a first reading value, and the analog signal is also controlled to be a residual magnetism value of an iron core of the under-test current conversion unit; and
a driving circuit, electrically connected to the control unit and under-test current conversion unit, wherein in the open-loop state, the driving circuit is configured to generate an alternating current signal, so as to generate positive and negative currents with a decreasing peak value on the coil and generate positive and negative magnetic fields with a decreasing peak value on the iron core for degaussing.

2. The closed-loop current sensor as claimed in claim 1, wherein in the open-loop state, the control unit is further configured to output the control signal with a second duty cycle, wherein the second duty cycle is different than the first duty cycle.

3. The closed-loop current sensor as claimed in claim 2, wherein in the open-loop state, the control unit is further configured to output the control signal with the first duty cycle plus a sinusoidal signal with a decreasing peak value having a third duty cycle, and the driving unit is further configured to generate the alternating current signal according to the control signal with the first duty cycle plus the sinusoidal signal with the decreasing peak value of the third duty cycle, wherein the third duty cycle is different than the first duty cycle.

4. The closed-loop current sensor as claimed in claim 3, wherein in a closed-loop state, the control unit is configured to output the control signal with the first duty cycle plus a corresponding reverse magnetic field, so as to control the current value of the coil of the under-test current conversion unit, and the under-test current conversion unit is configured to receive the under-test current and generate the voltage output signal.

5. The closed-loop current sensor as claimed in claim 1, wherein the first signal conversion unit is an analog-to-digital converter or a delta-sigma converter.

6. The closed-loop current sensor as claimed in claim 1, wherein the second signal conversion unit is an analog-to-digital converter or a delta-sigma converter.

7. The closed-loop current sensor as claimed in claim 1, wherein the under-test current conversion unit comprises:
a primary side, configured to input the under-test current, and generate a magnetic field;
a secondary side, configured to induce the magnetic field and generate an induced magnetic field, and to generate a current through a driving of the driving circuit and generate a reverse magnetic field;
a magnetic unit, configured to generate the analog signal through the induced magnetic field; and
a voltage generating unit, electrically connected to the secondary side, and configured to receive the current and generate the voltage output signal.

8. The closed-loop current sensor as claimed in claim 1, wherein the driving circuit comprises:
a first transistor, having a first terminal, a second terminal and a control terminal, wherein the first terminal of the first transistor is configured to receive a first reference voltage, the second terminal of the first transistor is electrically connected to the under-test current conversion unit, and the control terminal of the first transistor is electrically connected to the control unit; and
a second transistor, having a first terminal, a second terminal and a control terminal, wherein the first terminal of the second transistor is configured to receive a second reference voltage, the second terminal of the second transistor is electrically connected to the second terminal of the first transistor, and the control terminal of the second transistor is electrically connected to the control terminal of the first transistor.

9. An operation method of a closed-loop current sensor, comprising:
providing an under-test current conversion unit to input an under-test current, and generate an analog signal and a voltage output signal;
providing a first signal conversion unit to receive the analog signal, and convert the analog signal into a magnetic flux signal;
providing a second signal conversion unit to receive the voltage output signal, and convert the voltage output signal into a digital voltage output signal;
providing a control unit to be electrically connected to the first signal conversion unit and the second signal conversion unit, and to receive the magnetic flux signal and the digital voltage output signal;
providing a driving circuit to be electrically connected to the control unit and under-test current conversion unit;
in an open-loop state, using the control unit to output a control signal with a first duty cycle and to control a current value of a coil of the under-test current conversion unit, wherein the voltage output signal is a first reading value, and the analog signal is also controlled to be a residual magnetism value of an iron core of the under-test current conversion unit; and
in the open-loop state, using the driving circuit to generate an alternating current signal, so as to generate positive and negative currents with a decreasing peak value on the coil and generate positive and negative magnetic fields with a decreasing peak value on the iron core for degaussing.

10. The operation method of the closed-loop current sensor as claimed in claim 9, further comprising:
in the open-loop state, using the control unit to output the control signal with a second duty cycle, wherein the second duty cycle is different than the first duty cycle.

11. The operation method of the closed-loop current sensor as claimed in claim 10, further comprising:
in the open-loop state, using the control unit to output the control signal with the first duty cycle plus a sinusoidal signal with a decreasing peak value having a third duty cycle, wherein the third duty cycle is different than the first duty cycle;
wherein the step of using the driving circuit to generate the alternating current signal comprises:
using the driving unit to generate the alternating current signal according to the control signal with the first duty cycle plus the sinusoidal signal with the decreasing peak value of the third duty cycle.

12. The operation method of the closed-loop current sensor as claimed in claim 11, further comprising:
in a closed-loop state, using the control unit to output the control signal with the first duty cycle plus a corresponding reverse magnetic field, so as to control the current value of the coil of the under-test current conversion unit, and the under-test current conversion unit receiving the under-test current and generating the voltage output signal.

13. The operation method of the closed-loop current sensor as claimed in claim 9, wherein the first signal conversion unit is an analog-to-digital converter or a delta-sigma converter.

14. The operation method of the closed-loop current sensor as claimed in claim 9, wherein the second signal conversion unit is an analog-to-digital converter or a delta-sigma converter.
